(19) United States
(12) Patent Application Publication
(10) Pub. No.: US 2011/0255021 A1
(43) Pub. Date: Oct. 20, 2011

(54) ARRAY SUBSTRATE FOR LIQUID CRYSTAL PANEL, AND LIQUID CRYSTAL DISPLAY DEVICE COMPRISING THE SUBSTRATE

(75) Inventor: Ryoh Ohue, Osaka (JP)

(73) Assignee: SHARP KABUSHIKI KAISHA, Osaka (JP)

(21) Appl. No.: 13/141,971

(22) PCT Filed: Dec. 25, 2009
(86) PCT No.: PCT/JP2009/071589

§ 371 Date: Jun. 23, 2011

(30) Foreign Application Priority Data
Jan. 8, 2009 (JP) 2009-002767

(51) Int. Cl. G02F 1/1368; H01L 29/786

(52) U.S. Cl. 349/43; 257/59; 257/E29.289

(57) ABSTRACT

Disclosed is an array substrate (12) for liquid crystal panel, in which a thin film transistor (30) has a multi-layered structure including a gate electrode (32), an insulating layer (34), a semiconductor layer (35), a source electrode (36), and a drain electrode (37), which are disposed over a substrate main body (12a). Respective portions of the gate electrode (32) located under the source electrode (36) and the drain electrode (37) are formed as recessed portions (33a and 33b), which concave in from the surrounding portion, and the source electrode (36) and the drain electrode (37) are respectively formed above the recessed portions (33a and 33b).

### TECHNICAL FIELD

The present invention relates to a liquid crystal display device. More particularly, the present invention relates to an array substrate for liquid crystal panel used to constitute a liquid crystal display panel, and to a liquid crystal display device equipped with a liquid crystal panel having the array substrate for liquid crystal panel.

### BACKGROUND ART

Liquid crystal display devices equipped with liquid crystal panels are in wide use as image display devices (displays) for television, personal computers, and the like.

One of the features demanded in such liquid crystal display devices in recent years is further compactness and slimness (thinness) of liquid crystal display devices that is achieved without sacrificing the image display screen size. For example, in order to meet the demand for slimness in an active matrix type liquid crystal display device, which is described above, preferably the liquid crystal panel itself is configured to be thinner. One of the means to achieve the slimness of the liquid crystal panel itself is to reduce the thickness of metal wirings formed on one of the pairing substrates that face each other with a liquid crystal layer sandwiched in between (that is, the paring substrates are typically an array substrate, which is also called a TFT substrate, and an opposite substrate, which faces the array substrate and is also called a color filter substrate).

### RELATED ART DOCUMENTS

### Patent Documents

Patent Document 1: Japanese Patent Application Laid-Open Publication No. H6-235934
Patent Document 2: Japanese Patent Application Laid-Open Publication No. H11-218781

### SUMMARY OF THE INVENTION

### Problems to be Solved by the Invention

Although no problem should arise by reducing the thickness of a metal wiring if the metal wiring is simply formed on a substrate, problems such as described below could occur when the wires cross each other. That is, at a portion where a gate wire and a source wire constituting a pixel drive circuit intersect on an array substrate (TFT substrate), the wire that is disposed on top (the wire that is disposed over the other that is already in place) can become narrow when it crosses over the other wire underneath. Such case is described with reference to the schematic view shown in FIG. 9.

For example, when wiring is disposed using a general photolithographic method (photolithography), as shown in FIG. 9, a surface protrusion by the presence of a gate wire 222, which is already in place on an array substrate 212, causes a difference in exposure depth at the location where a source wire 224 climbs over (crosses over) the gate wire 222. As a result, the line width becomes smaller as illustrated, and in the worst case, the wire can break at the location where one wire climbs over (crosses over) the other. In order to prevent such wire breakage (that is, to prevent a slight difference in exposure depth from giving any influence), the thickness of the wire that crosses over the other (in FIG. 9, this is the source wire 224) should be made greater. However, this is contrary to the objective of slimming down the liquid crystal panel and therefore is not preferable. Although Patent Documents 1 and 2 disclose related technologies for slimming down the liquid crystal panel, they are not the technologies that solve the problem described above.

Also, by reducing the thickness of the liquid crystal panel, the space between the two substrates (an array substrate and a color filter substrate) becomes narrower accordingly. This increases the chance that undesirable short-circuits is triggered by mere presence of impurities such as fine dusts between the substrates. Therefore, a thin liquid crystal panel having a structure that can prevent the occurrence of short-circuits is desirable.

The present invention was devised to solve the problems described above, and its main objective is to provide an array substrate for liquid crystal panel in which thin metal wirings are formed without causing wire breakages, and a liquid crystal panel equipped with such substrate.

Another objective is to provide a thin liquid crystal panel having a structure in which short-circuits are difficult to occur, and an array substrate for liquid crystal panel suitable for constituting such panel.

Yet another objective is to provide a liquid crystal display device equipped with such liquid crystal panel having a structure in which wire breakages are unlikely and/or short-circuits are difficult to occur.

### Means for Solving the Problems

An array substrate for liquid crystal panel according to an embodiment of the present invention includes a substrate main body, a plurality of gate wires, a plurality of source wires that cross the gate wires, and a plurality of thin film transistors that are electrically connected to the respective gate wires and the source wires. The gate wires arranged on the substrate main body are formed to concave in at the location where they are to intersect with the source wires, and therefore form portions that are recessed below the non-intersecting portion adjacent to the intersecting portion. Also, the source wires are arranged to cross the gate wires at the recessed portions of the gate wires.

In the array substrate for liquid crystal panel according to the present invention, the portion of the gate wire at which the source wire may cross is formed as recessed. Consequently, as the source wire crosses over the recessed portion, the situation in which the source wire rises by “climbing” over the gate wire at the intersecting portion can be avoided. This reduces any difference in exposure depth between the intersecting portion and non-intersecting portion during exposure for source wire formation, and consequently, the source wire maintains about the same line width at the intersecting portion as at the non-intersecting portion.

Also, compared to the case where the source wire is disposed over conventionally disposed gate wire without any recessed portion, the source wire at the intersecting portion does not have as much thickness (height) in the direction of the rise of the source wire, but is formed deeper (i.e., thicker) as much as the depth of the recessed portion. Consequently, the source wire obtains enough width and thickness in both the direction of width and the direction of depth at the portion where it intersects with the gate wire.

Therefore, according to the array substrate for liquid crystal panel, a metal wiring in which enough width and thickness are secured for the source wires to avoid wire breakage while the overall thickness of the wiring is suppressed small can be provided.

Also, for the array substrate for liquid crystal panel according to the present invention, because of the aforementioned recessed portion, the situation where the source wire rises as it climbs over the gate wire at the intersecting portion can be avoided. As a result, in a liquid crystal panel composed of such array substrate and a color filter (CF) substrate, which face each other, the interval between the array substrate and the CF substrate at the intersecting portion is maintained about the same as the interval at the non-intersecting portion. Consequently, short-circuits between the substrates at the intersecting portion can effectively prevented from occurring.

Therefore, according to the array substrate for liquid crystal panel of the present invention, a thin liquid crystal panel having a structure in which short-circuits between the array substrate and the CF substrate are difficult to occur can be provided.

An preferred embodiment of the array substrate for liquid crystal panel disclosed herein is characterized by a nearly constant width of the top surface of the source wire at the intersecting portion and at the portions adjacent to both sides of the intersecting portion.

For an array substrate for liquid crystal panel having such a configuration, the width of the top surface of the source wire is kept nearly constant at the intersecting portion and at the portion adjacent to the intersecting portion. This allows prevention of the short-circuit occurrence between the substrates at the intersecting portion at a higher level.

An array substrate for liquid crystal panel according to a preferred embodiment of the present invention includes a substrate main body, a plurality of gate wires, a plurality of source wires that cross the gate wires, and a plurality of thin film transistors electrically connected to the respective gate wires and the source wires. The thin film transistor has a multi-layered structure that includes a gate electrode formed on the substrate main body, an insulating layer formed over the gate electrode, a semiconductor layer formed over the insulating layer, and a source electrode and a drain electrode formed over the semiconductor layer. Here, respective portions of the gate electrode that are located under the source electrode and the drain electrode are formed as recessed below the surrounding portion, and is characterized in that the source electrode and the drain electrode are formed over the respective recessed portions.

For the array substrate for liquid crystal panel having such configuration, in the thin film transistor of a multi-layered structure provided on the array substrate, the source electrode and the drain electrode are formed (layered) over the respective recessed portions formed in the gate electrode. Therefore, for the liquid crystal panel in which the array substrate and the CF substrate are disposed facing each other, the space between the array substrate and the CF substrate where the source electrode and the drain electrode are formed is maintained about the same as the space at the surrounding region. As a result, short-circuits due to the presence of impurity or the like can effectively be prevented from occurring between the substrates. Therefore, with the array substrate of such configuration, a thin liquid crystal panel having a structure where short-circuits are difficult to occur between the array substrate and the CF substrate can be provided.

In an embodiment of the liquid crystal panel for array substrate disclosed herein, a source electrode and a drain electrode formed over the respective recessed portions are disposed as surrounded by another layer formed under the electrodes, and the top surface portions of the electrodes are flush with the top edge surface of the layer surrounding the electrodes, without any level difference.

In the array substrate for liquid crystal panel having such configuration, the top surface portions of the source electrode and the drain electrode are flush with the top edge surface of the area that surrounds the electrodes. With this configuration, the space between the array substrate and the CF substrate where the source electrode and the drain electrode are formed is about the same as the space between the substrates at the area surrounding the electrodes. As a result, with the array substrate having such a configuration, short-circuits between the substrates can even more reliably be prevented.

In a preferred embodiment of the array substrate for liquid crystal panel disclosed herein, the gate electrode has a multi-layered structure composed of two layers or three or more layers, and the recessed portions are formed in a lower layer portion, excluding the top layer, of the multi-layered structure.

For the array substrate having such configuration, the recessed portions are formed in the gate electrode having a multi-layered structure, in the lower layer portion excluding the top layer (that is, in the lower layer portion, the thickness of the recessed portions is different from the thickness of the portion surrounding the recessed portions). Therefore, the top layer does not need to be formed with a film thickness as thick as or thicker than the depth of the recessed portions. In the multi-layered structure, recessed portions are preferably formed in a layer made of a material that allows easy formation of recessed portions (aluminum (Al), for example).

Also, the present invention provides a liquid crystal panel equipped with the array substrate disclosed herein, as another aspect of the present invention.

Because a liquid crystal panel according to the present invention is equipped with the array substrate for liquid crystal panel described above, both the thin structure with small panel thickness and a structure in which wire breakages are unlikely and/or short-circuits are hard to occur can be provided.

The present invention also provides a liquid crystal display device equipped with a liquid crystal panel that can deliver such effects.

### BRIEF DESCRIPTION OF THE DRAWINGS

FIG. 1 is an exploded perspective view schematically showing the configuration of the liquid crystal display device according to an embodiment.

FIG. 2 is a cross-sectional view showing the configuration of the liquid crystal display device according to an embodiment.

FIG. 3 is a cross-sectional view showing the configuration of the liquid crystal panel according to an embodiment.

FIG. 4 is a plan view showing the pixel region of the array substrate for liquid crystal panel according to an embodiment.

FIG. 5 is a cross-sectional view taken along the line V-V of FIG. 4, schematically showing the multi-layered structure of the thin film transistor (TFT).

FIG. 6A is a cross-sectional view schematically showing the array substrate according to an embodiment, in which a lower layer and a middle layer that constitute the gate electrode are layered over the substrate main body that constitutes the array substrate.

FIG. 6B is a cross-sectional view schematically showing a resist formed at a prescribed location on the middle layer of the gate electrode.

FIG. 6C is a cross-sectional view schematically showing the middle layer of the gate electrode as it is patterned after photolithography is conducted.

FIG. 6D is a cross-sectional view schematically showing the upper layer that constitutes the gate electrode as it is layered on the patterned middle layer of the gate electrode.

FIG. 6E is a cross-sectional view schematically showing the insulating layer and the semiconductor layer as they are layered over the gate electrode.

FIG. 6F is a cross-sectional view schematically showing a resist as it is formed at a prescribed location on the semiconductor layer.

FIG. 6G is a cross-sectional view schematically showing the semiconductor layer patterned after photolithography is conducted.

FIG. 6H is a cross-sectional view schematically showing the lower layer and the upper layer of the metal film layer that constitutes the source electrode and the drain electrode as they are layered over the patterned semiconductor layer.

FIG. 6I is a cross-sectional view schematically showing a resist formed at a prescribed location on the upper layer of the metal film layer constituting the source electrode and the drain electrode.

FIG. 6J is a cross-sectional view schematically showing the metal film layer after the photolithography.

FIG. 6K is a cross-sectional view schematically showing the source electrode and the drain electrode as patterned.

FIG. 7 is a cross-sectional view schematically showing the multi-layered structure of a TFT of a conventional array substrate.

FIG. 8 is a plan view schematically showing the intersecting portion of a source wire and a gate wire of an array substrate according to another embodiments.

FIG. 9 is a plan view schematically showing the intersecting portion of a source wire and a gate wire of a conventional array substrate.

### DETAILED DESCRIPTION OF EMBODIMENTS

Below, preferred embodiments of the present invention are described with reference to figures. Matters not specifically mentioned herein (matters other than the configuration of and constituting method of liquid crystal panel, for example), but necessary to implement the present invention (configuration of the light source provided on the liquid crystal display device, electrical circuits involved in the drive system of the light source, and the like, for example) can be worked out as design matters by those skilled in the art based on conventional technologies in the field. The present invention can be implemented based on the contents disclosed herein and common technical knowledge in the field.

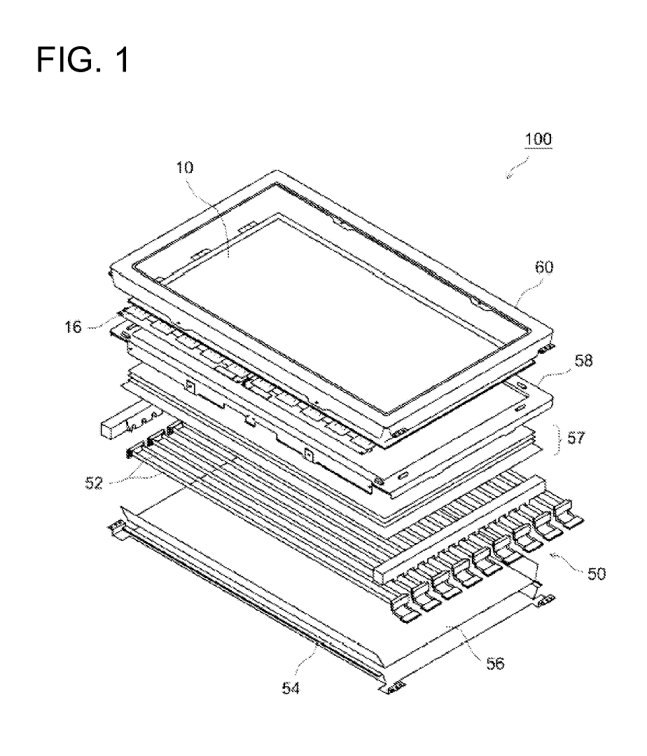

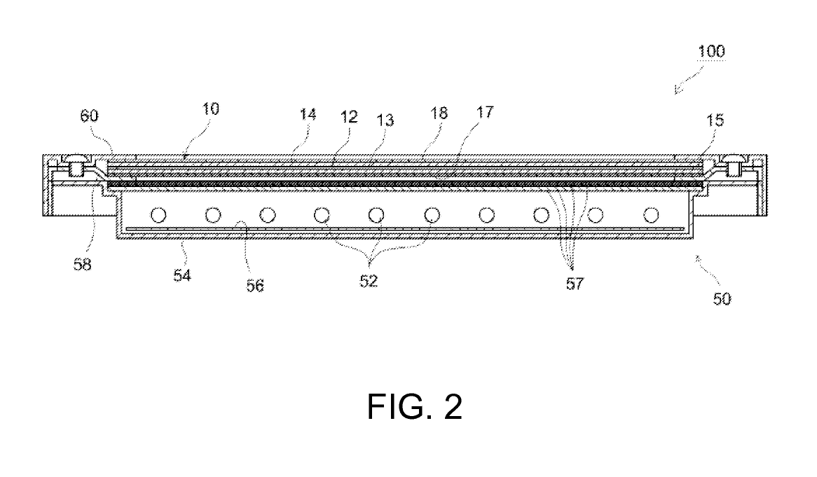

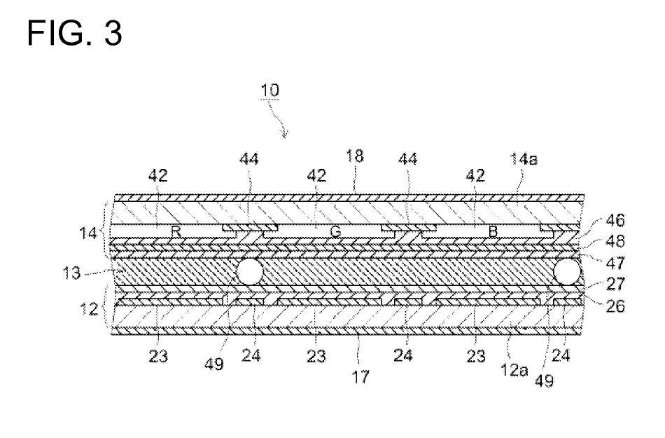

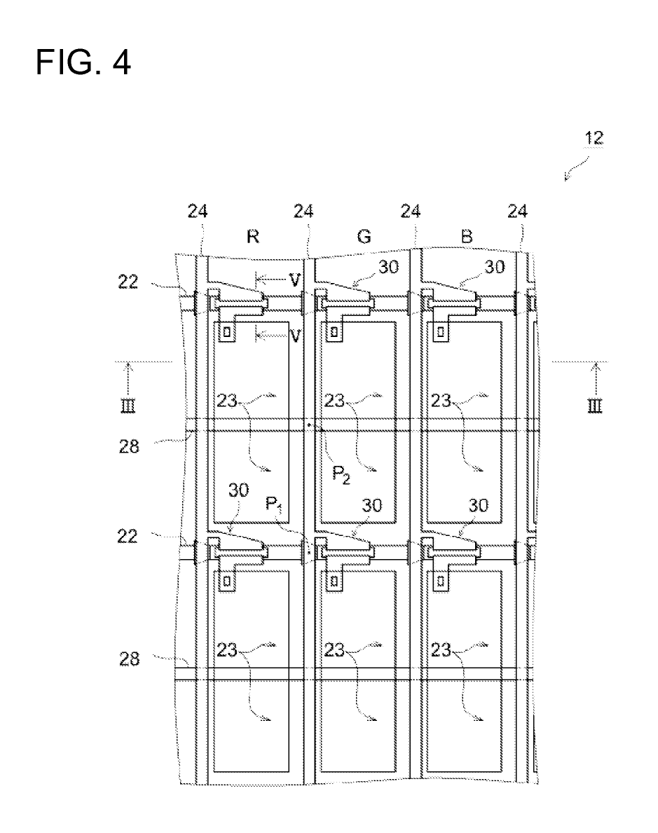

Below, a liquid crystal panel 10 equipped with an array substrate 12 for liquid crystal panel according to a preferred embodiment of the present invention, and an active matrix (TFT-type) liquid crystal display device 100 including the liquid crystal panel 10 are described below with reference to FIG. 1 to FIG. 4. FIG. 1 is an exploded perspective view schematically showing the configuration of the liquid crystal display device 100 according to an embodiment. FIG. 2 is a cross-sectional view schematically showing the configuration of the liquid crystal display device 100 according to an embodiment. FIG. 3 is a cross-sectional view schematically showing the configuration of the liquid crystal panel 10. FIG. 4 is a plan view schematically showing the array substrate 12 for liquid crystal panels according to an embodiment.

In the following figures, members and portions having the same functions may be assigned with the same reference characters and redundant descriptions may be abridged or avoided. Also, the dimensional relationship (length, width, thickness, and the like) in each of the figures does not necessarily reflect the actual dimensional relationship accurately. In the description below, “over” or “front side” refers to the side close to the viewer of the liquid crystal display device 100 (that is, the liquid crystal panel side), and “under” or “back side” refers to the side away from the viewer of the liquid crystal display device 100 (that is, the backlight device side).

Configuration of the liquid crystal display device 100 is described with reference to FIG. 1 and FIG. 2. As shown in FIG. 1, the liquid crystal display device 100 includes a liquid crystal panel 10 and a backlight device 50, which is an external light source disposed on the back side of the liquid crystal panel 10 (close to the bottom of FIG. 1). The liquid crystal panel 10 and the backlight device 50 are coupled together by a frame body (bezel) 60 or the like and are held unitarily.

The liquid crystal panel 10 is described with reference to FIG. 1 to FIG. 4.

As shown in FIG. 1 to FIG. 3, the liquid crystal panel 10 has generally a rectangular shape overall, and has a pixel formation region, in which pixels are formed, in the center area (also referred to as an effective display region, or an active area). Also, the liquid crystal panel 10 has a sandwich structure composed of a pair of transparent glass substrates 12 and 14 that face each other, and a liquid crystal layer 13 sealed between them. The substrates 12 and 14 were separated from a large base material called “mother glass” in the manufacturing process. Out of the pairing substrates 12 and 14, the one close to the front side is a color filter substrate (CF substrate) 14, and the one close to the back side is an array substrate 12. Along the margin areas of the array substrate 12 and the CF substrate 14 (margin area on the liquid crystal panel 10), a sealing member 15 is provided. The sealing member 15 seals in the liquid crystal layer 13. The liquid crystal layer 13 is made of a liquid crystal material containing liquid crystal molecules. Orientation of the molecules in the liquid crystal material is controlled by the electrical field applied between the substrates 12 and 14, and its optical properties change accordingly. To the substrates 12 and 14, polarizing plates 17 and 18 are attached, respectively, on the side away from the facing substrate (outside).

For the liquid crystal panel 10 disclosed herein, as shown in FIG. 3 and FIG. 4, on the front side (the side facing the liquid crystal layer 13) of a glass substrate main body 12a that constitutes the array substrate 12, pixels for displaying images (more accurately, sub-pixels) are arranged, and a plurality of gate wires 22 and source wires 24 (also may be referred to as “metal wirings 22 and 24”) for driving individual pixels are formed in a grid pattern. In each grid box bordered by the metal wirings 22 and 24, a pixel electrode 23 and a thin film transistor (TFT) 30, which is a switching element, are provided. Typically, the pixel electrode 23 is made of ITO (Indium Tin Oxide), a transparent conductive material. For each pixel electrode 23, voltages according to images are sent at a predetermined timing through the metal wirings 22 and 24 and the thin film transistor 30.

As shown in FIG. 1, the gate wire 22 and the source wire 24 are typically connected to an external driver circuits (driver ICs) 16, which are provided in the margin area of the liquid crystal panel 10, and can supply image signals and the like.

As shown in FIG. 3, the pixel electrode 23, the gate wire 22, and the source wire 24 are covered by a planarizing layer (also referred to as overcoat layer) 26, which is made of an insulating material. On the planarizing layer 26, an alignment film 27 made of polyimide or the like is formed. The surface of the alignment film 27 was subjected to an alignment treatment (rubbing treatment), by which alignment of liquid crystal molecules when no voltage is applied is determined. The rubbing treatment is not always required. For example, if the liquid crystal panel 10 according to this embodiment is categorized as the VA (Vertical Alignment) type in which vertical alignment film is used, the rubbing treatment discussed above does not need to be performed.

On the other hand, as shown in FIG. 3, on the back side (the side facing the liquid crystal layer 13) of a glass substrate main body 14a constituting the CF substrate 14, color filters 42 and a black matrix (light-shielding film) 44 that borders the color filters 42 of the respective colors are formed at the locations corresponding to respective pixel electrodes 23 of the array substrate 12. Each of the color filters has one of the three colors: red (R), green (G), or blue (B). Each of the pixel electrodes 23 of the array substrate 12 faces one color filter 42 of R, G, or B. The black matrix 44 is made of a metal such as Cr (chrome) so that it can block the light from passing through the regions between the sub-pixels. As shown in FIG. 3, the planarizing layer 46 is formed to cover the color filters 42 and the black matrix 44. On the surface of the planarizing layer 46, an opposite electrode (common electrode) 48 made of ITO is formed. On the surface of the opposite electrode 48, an alignment film 47 is formed. The surface of the alignment film 47 is subjected to an alignment treatment (as in the case of the alignment film 27, the alignment film treatment does not always need to be conducted). Also, typically, the alignment direction of the alignment film 27 of the array substrate 12 and the alignment direction of the alignment film 47 of the CF substrate 14 are different by 90°.

Between the array substrate 12 and the CF substrate 14, as shown in FIG. 3, a plurality of spacers 49, which may be ball-shaped or cylinder-shaped (they are ball-shaped in FIG. 3), are dispersed and sandwiched. The spacer 49 is made of, for example, a resin material that can be elastically deformed. With this configuration, the gap (space) between the substrates 12 and 14 is maintained by the sealing member 15 (see FIG. 2) and the spacers 49, and the thickness of the liquid crystal layer 13 is kept constant.

Also, as shown in FIG. 2 and FIG. 3, polarizing plates 17 and 18 are attached to the substrates 12 and 14, respectively, on the sides not facing each other.

As shown in FIG. 1 and FIG. 2, a bezel 60 is attached on the front side of the liquid crystal panel 10. Also, on the back side of the liquid crystal panel 10, a frame 58 is attached. The bezel 60 and the frame 58 hold the liquid crystal panel 10 between them. Furthermore, the frame 58 has an opening portion that corresponds to the effective display region, which is the central portion of the liquid crystal panel 10. On the back side of the liquid crystal panel 10, a backlight device 50 housed in a case 54 is attached.

As shown in FIG. 1, the backlight device 50 is composed of a plurality of linear light sources (e.g., fluorescent tubes; typically cold-cathode tubes) 52 and a case (chassis) 54 that houses the light sources 52. The case 54 is a box-shaped with the opening facing the front side. Inside the case 54, the light sources 52 are arranged in parallel with each other. Between the case 54 and the light sources 52, a reflective member 56 is disposed for efficiently reflecting the light from the light sources 52 towards the viewer.

The opening portion of the case 54 is covered by an optical member 57, which is a plurality of sheet-shaped layers. The optical member 57 is composed of, for example, a diffusion plate, a diffusion sheet, a lens sheet, a luminance increase sheet, and the like in this order from the side closer to the backlight device 50, but is not limited to this combination or order. Furthermore, for holding the optical member 57 in place in the case 54, the above-mentioned frame 58, which is substantially in frame-shape, is provided for the case 54.

On the back side of the case 54, an inverter circuit substrate (not shown) for mounting an inverter circuit and an inverter transformer (not shown) as a booster circuit for supplying power to respective light sources 52 are provided. These items, however, do not characterize the present invention, and therefore descriptions on them are omitted.

The liquid crystal display device 100 having the configuration described above operates the liquid crystal molecules in the liquid crystal layer 13 by applying the controlled voltages on the array substrate 12 and the CF substrate 14, and transmits or blocks the light from the backlight device 50 at the liquid crystal panel 10. The liquid crystal display device 100 also displays desired images in the effective display area of the liquid crystal panel 10, while controlling the luminance and the like of the backlight device 50.

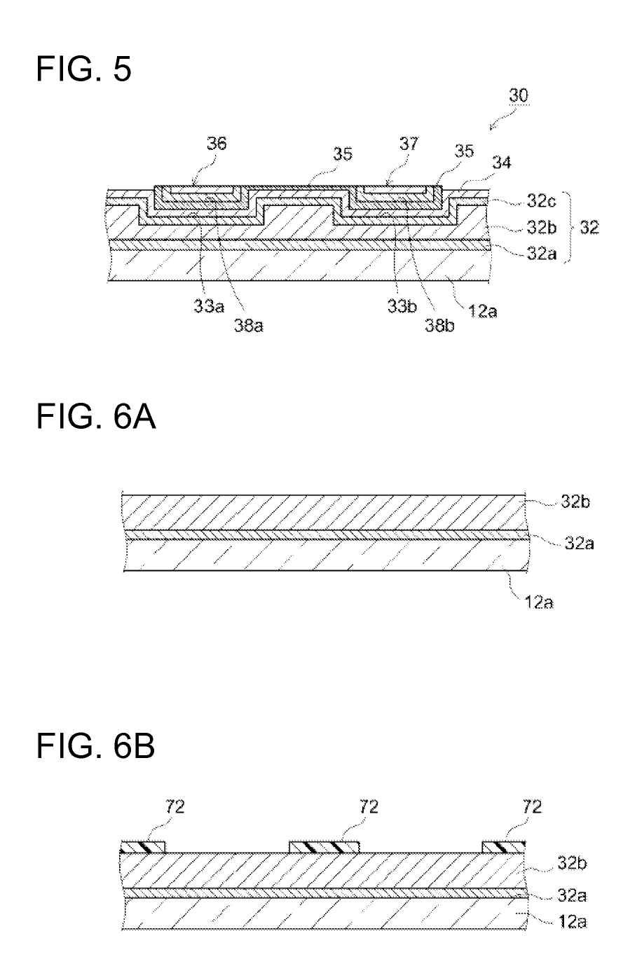

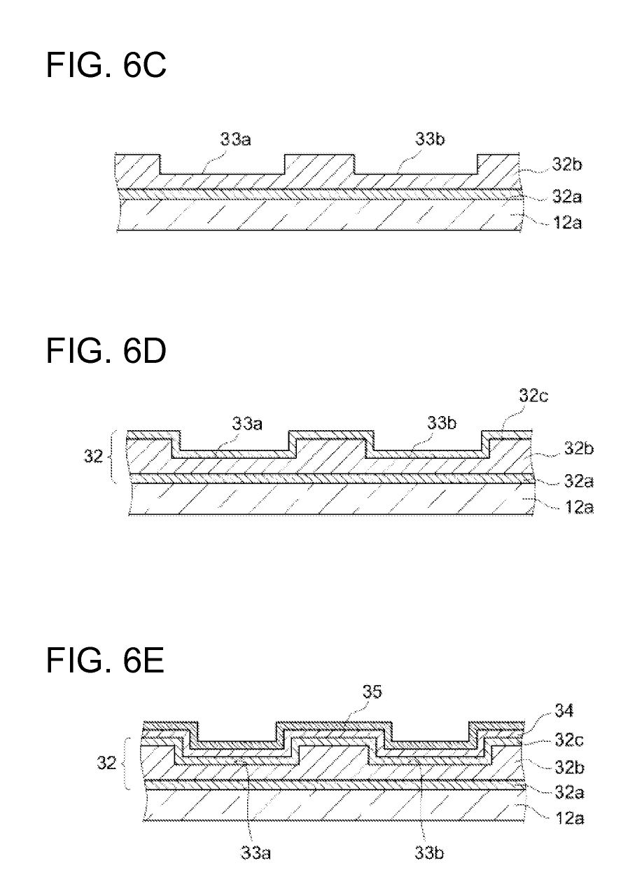

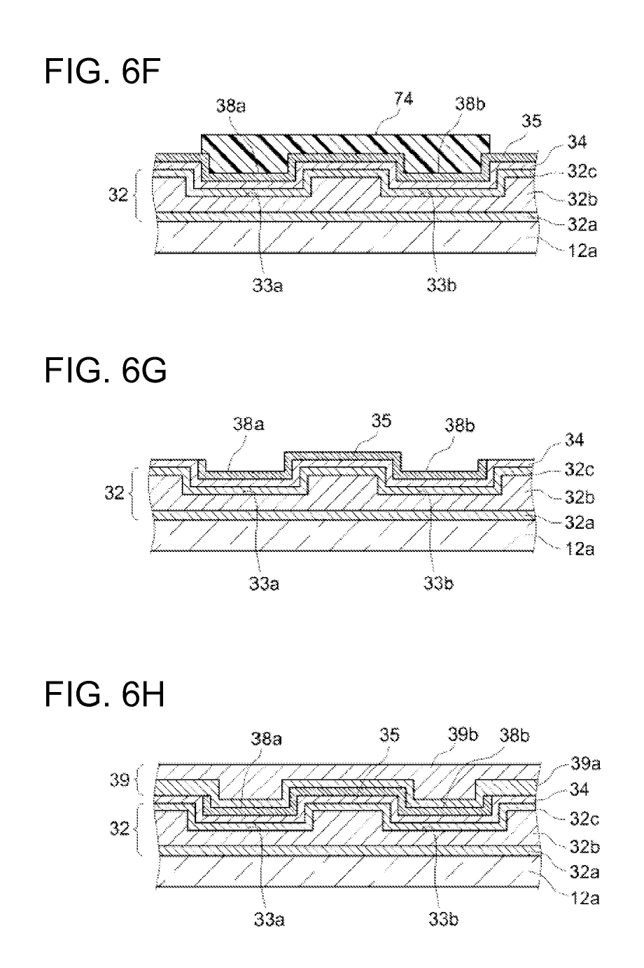

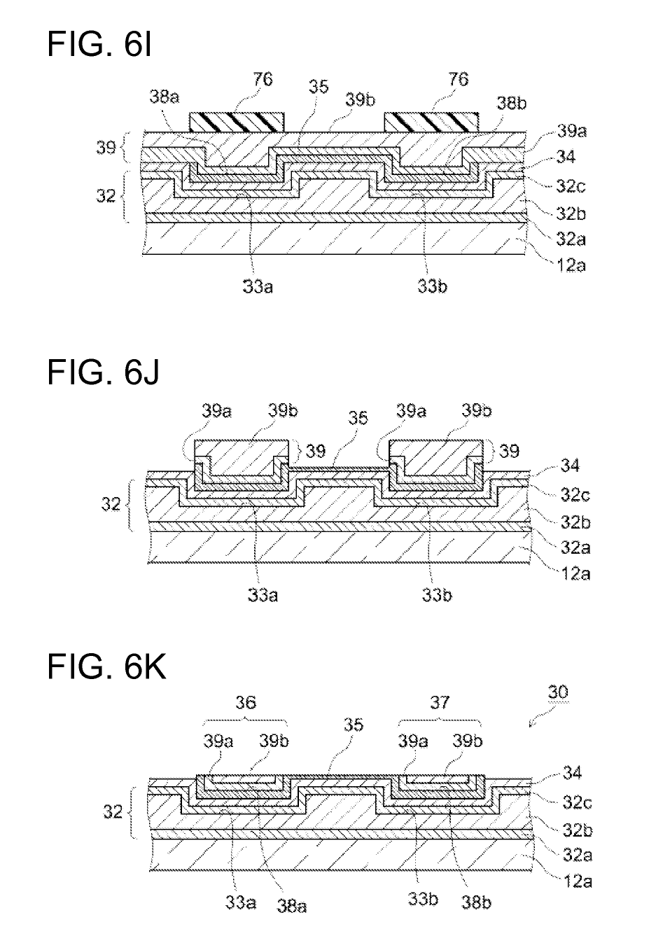

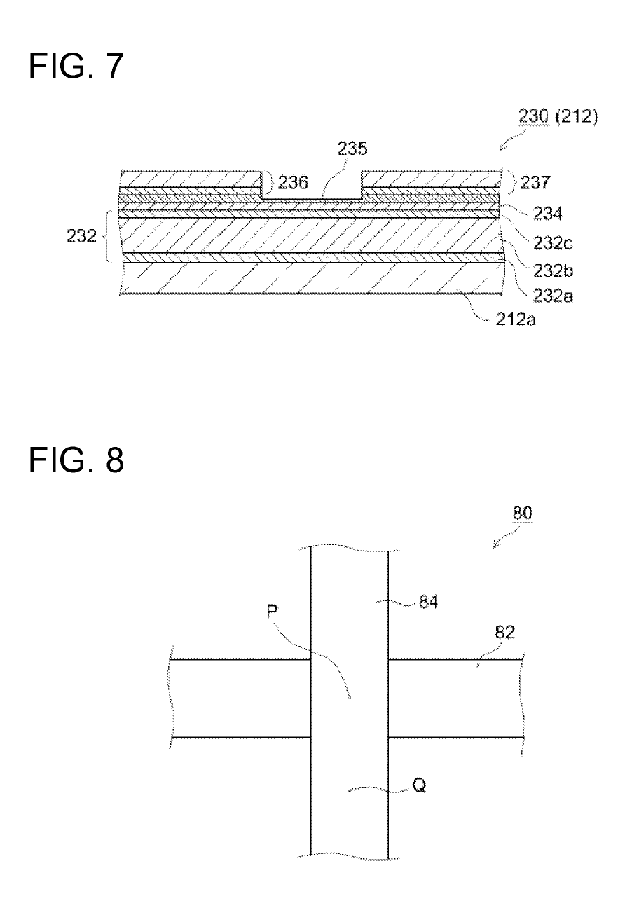

Next, with reference to FIG. 5 to FIG. 8, the thin film transistor (hereinafter may be simply referred to as “TFT”) 30 on the array substrate 12 according to this embodiment is further described. FIG. 5 is a cross-sectional view taken along the line V-V of FIG. 4, and schematically shows the multi-layered structure of TFT 30. FIG. 6 is a cross-sectional view schematically showing sequentially the steps of forming the multi-layered structure of the TFT 30. FIG. 6A is a cross-sectional view showing a lower layer 32a and a middle layer 32b, which constitute the gate electrode 32, as they are layered over the substrate main body 12a, which constitutes the array substrate 12. FIG. 6B is a cross-sectional view schematically showing a resist 72 as it is disposed at a prescribed location on the middle layer 32b. FIG. 6C is a cross-sectional view schematically showing the middle layer 32b as patterned after the photolithography is conducted. FIG. 6D is a cross-sectional view schematically showing an upper layer 32c, which constitutes the gate electrode 32, as it is layered over the patterned middle layer 32b. FIG. 6E is a cross-sectional view schematically showing an insulating layer 34 and a semiconductor layer 35 as they are layered over the gate electrode 32, which was layered as described above. FIG. 6F is a cross-sectional view showing a resist 74 as it is formed at a prescribed location on the semiconductor layer 35. FIG. 6G is a cross-sectional view schematically showing the semiconductor layer 35 as it is patterned after the photolithography is conducted. FIG. 6H is a cross-sectional view schematically showing a lower layer 39a and an upper layer 39b of a metal film layer 39 that constitute the source electrode 36 and the drain electrode 37, as they are layered over the patterned semiconductor layer 35. FIG. 6I is a cross-sectional view schematically showing resists 76 as they are formed on the upper layer 39b at predetermined locations. FIG. 6J is a cross-sectional view schematically showing the metal film layer 39 after the photolithography is conducted. FIG. 6K is a cross-sectional view schematically showing the source electrode 36 and the drain electrode 37 as they are patterned. FIG. 7 is a cross-sectional view schematically showing the multi-layered structure of TFT 230 in a conventional array substrate 212. FIG. 5 and FIG. 6A to FIG. 6K are schematic cross-sectional views, and therefore they do not exactly match the schematic plan view of FIG. 4.

As described above, the array substrate 12 of the liquid crystal panel 10 according to this embodiment includes a glass substrate main body 12a, a plurality of gate wires 22, a plurality of source wires 24 that intersect with the gate wires 22 at a right angle, and a plurality of TFTs 30 that are electrically connected to the respective gate wires 22 and source wires 24. For the array substrate 12 according to this embodiment, TFT 30 is disposed over the gate wire 22 (more specifically, over the gate wire 22 near the intersecting portion P₁ with the source wire 24 (see FIG. 4)) for higher pixel aperture ratio. As shown in FIG. 5, the TFT 30 has an inversely-staggered, multi-layered structure that includes a gate electrode 32 formed on the substrate main body 12a, an insulating (film) layer 34 formed (layered) over the gate electrode 32, a semiconductor layer 35 formed over the insulating layer 34, and a source electrode 36 and a drain electrode 37 formed over the semiconductor layer 35.

As shown in FIG. 5, the gate electrode 32 according to this embodiment has a three-layer structure in which an aluminum (Al) layer is sandwiched by titanium (Ti) layers. That is, the three-layer structure is constituted of a lower layer 32a, which is made of Ti and is formed on the substrate main body 12a, a middle layer 32b, which is made of Al and is formed on the lower layer 32a, and an upper layer 32c, which is made of Ti and is layered on the middle layer 32b. For the middle layer 32b of the gate electrode (gate electrode layer) 32, in the areas located under the areas where the source electrode 36 and the drain electrode 37 are formed, recessed portions 33a and 33b are formed, which concave in from the surrounding area (region) by a predetermined depth. Over the recessed portions 33a and 33b, the upper layer 32c, the insulating layer 34, and the semiconductor layer 35 are layered in this order to form recessed portions 38a and 38b. In the recessed portions 38a and 38b, the source electrode 36 and the drain electrode 37 are formed, respectively.

The insulating layer 34 formed on the upper layer 32c of the three-layered gate electrode 32 functions as a gate insulating film. The insulating layer 34 is, as in the case with the gate insulating film of a conventional TFT, is composed of nitride product of silicon (Si) (SiNₓ) and/or oxidation product of silicon (SiOₓ) or the like. The insulating layer 34 may also be a multi-layered structure (a double-layered structure, for example). The portion of the insulating layer 34 that is located over the recessed portions 33a and 33b of the gate electrode 32 concaves in as corresponding to recessed portions 33a and 33b.

The semiconductor layer 35, which is formed in recessed portions of the insulating layer 34 as corresponding to the recessed portions 33a and 33b, is composed of an amorphous silicon (α-Si) layer that functions as a switch for TFT 30, and an n⁺ amorphous silicon (n⁺α-Si) layer that is layered over the α-Si layer. The n⁺α-Si layer is disposed to provide a good ohmic contact between the α-Si layer, and the source electrode 36 and the drain electrode 37. The n⁺α-Si layer is made of α-Si doped with a phosphorus (P) impurity. Here, an insulating layer that functions as a channel protective film (also called “i-stopper film”) and is made of SiNₓ may be disposed between the α-Si layer and the n⁺ α-Si layer. The portions of the semiconductor layer 35 (the n⁺ α-Si layer, to be exact) located over the recessed portions 33a and 33b of the gate electrode 32 are recessed portion 38a and 38b, which concave in as corresponding the recessed portions 33a and 33b.

On the recessed portions 38a and 38b of the semiconductor layer 35, a source electrode 36 and a drain electrode 37 are formed. The electrodes 36 and 37 are both made of a metal film layer 39 having a two-layer structure (see FIG. 6I). The metal film layer 39 is composed of a lower layer 39a made of Ti and an upper layer 39b made of Al. As shown in FIG. 5, the electrodes 36 and 37 are disposed as if embedded in the recessed portions 38a and 38b formed in the semiconductor layer 35 that is layered under the electrodes 36 and 37, in such manner as to be surrounded by the semiconductor layer 35. The top surface portions of the electrodes 36 and 37 are flush with the top edge surface of the semiconductor layer 35 surrounding the electrodes 36 and 37.

With the configuration described above, TFT 30 of this embodiment has a multi-layered structure in which the source electrode 36 and the drain electrode 37 do not protrude from the surrounding area and provide an approximately flat surface.

Next, with reference to FIG. 6A to FIG. 6K and FIG. 7, an example of the method for manufacturing an array substrate 12 and a liquid crystal panel 10 having the array substrate 12 is described, focusing on the TFT 30 region. In the manufacturing process for the array substrate 12 of this embodiment, the order and the type (film material) of thin films layered by lithography can be similar to those of conventional array substrates, and there is no special limitation.

First, a substrate main body 12a cut out from a mother glass is prepared. The substrate main body 12a is washed (wash process). Next, as shown in FIG. 6A, the lower layer 32a made of Ti and the middle layer 32b made of Al, which will be the gate electrode 32, are deposited (vapor-deposited) by sputtering (film formation process). In this embodiment, the film thickness of the lower layer 32a is 30 nm, and the film thickness of the middle layer 32b is 360 nm. Next, the substrate main body 12a on which the lower layer 32a and the middle layer 32b are formed is washed, and a resist (film) 72 made of an ultraviolet-photosensitive resin is applied on the middle layer 32b (resist application process). The resist film (a positive resist film, for example) 72 is cured by pre-baking (pre-drying) (pre-baking process). Next, a patterned mask is placed on the cured resist film, and over the mask the ultraviolet ray having a specified wavelength (the i line having a wavelength of 365 nm, for example) is radiated for exposure (exposure process). After the exposure, the substrate main body 12a is immersed in the developing solution, and then rinsed with pure water to remove the exposed portion of the positive resist film 72 by dissolving (development process). Next, post-baking is performed (post-baking process). Through these processes, as shown in FIG. 6B, a resist film 72 (unexposed portion of the positive resist film) on which the mask pattern is transferred, is formed on the middle layer 32b.

Next, etching is conducted to form recessed portions 33a and 33b having a prescribed depth in prescribed regions of the middle layer 32b where the resist film 72 is not formed (etching process). For the etching process, dry etching utilizing the plasma-generated gas phase radicals can preferably be used. Here, the depth of the recessed portions 33a and 33b is set by appropriately adjusting the etching process conditions (etching rate, for example). The depth of the recessed portion 33 according to this embodiment is 150 nm. Lastly, by using plasma (dry) ashing or the like, for example, the resist film 72 is removed (resist removal process).

Through the processes described above, as shown in FIG. 6C, a substrate main body 12a that includes a lower layer 32a constituting the gate electrode 32, and a middle layer 32b layered on the lower layer 32a and having recessed portions 33a and 33b formed in the top surface can be obtained.

Next, as shown in FIG. 6D and FIG. 6E, an upper layer 32c, which is made of Ti and constitutes the gate electrode 32, an insulating layer (gate insulating film) 34, and a semiconductor layer 35 are formed in this order over the middle layer 32b on which recessed portions 33a and 33b have been formed in the film formation process. Here, the insulating layer 34 made of SiNₓ or the like, the semiconductor layer 35 having a two-layered structure of an α-Si layer and an n⁺ α-Si layer, and a channel protective film layer that may be interposed between the layers of the semiconductor layer 35 having the two-layered structure can continuously be formed as four layers by plasma CVD. In this embodiment, the film thickness of the upper layer 32c is 100 nm, the film thickness of the insulating layer 34 is 410 nm, the film thicknesses of the α-Si layer and the n⁺ α-Si layer of the semiconductor layer 35 are 235 nm and 550 nm, respectively, and the film thickness of the channel protective film is 265 nm. Those film thicknesses are not limited to the numerical values stated above, however, and they may be modified as appropriate.

Also, as shown in FIG. 6F and FIG. 6G, over the four layers formed in the film formation process, a resist 74 is applied in the resist application process. Then, through a series of processing of the pre-baking, exposure, development, post-baking, etching, and resist removal, the semiconductor layer 35 (n⁺ α-Si layer, to be exact) is patterned, and recessed portion 38a and 38b, which concave in from the surrounding surface, are formed.

Next, as shown in FIG. 6H, in a manner similar to above, a lower layer 39a, which is made of Ti and is a layer of the two-layered metal film layer 39 that will be the source electrode 36 and the drain electrode 37, is formed over the semiconductor layer 35, and on the lower layer 39a, an upper layer 39b made of Al is formed. Here, the lower layer 39a of this embodiment was formed by sputtering to achieve a film thickness of 30 nm, and the upper layer 39b was formed by sputtering to obtain a film thickness of 200 nm for the portion other than the recessed portions 38a and 38b.

Also, as shown in FIG. 6I and FIG. 6J, a resist (film) 76 is formed on the upper layer 39b. Subsequently, through processes such as exposure, development, etching, and resist removal, a metal film layer 39 is preserved only for portions of the upper layer 39b corresponding to the recessed portions 38a and 38b, and the metal film layer 39 is removed for the remaining portion. In the etching process, preferably the portion between the two recessed portions 38a and 38b (channel) is etched away until the semiconductor layer 35 (the surface layer of the channel protective film formed between the α-Si layer and the n⁺ α-Si layer, to be exact) is exposed.

Next, by applying a method similar to Damascene (embedding) method, for example, to the metal film layer 39 preserved for the recessed portions 38a and 38b, the source electrode 36 and the drain electrode 37 of a two-layered structure can be formed as embedded in the recessed portions 38. That is, as shown in FIG. 6J, for the metal film layer 39 located over the recessed portions 38a and 38b, the portion that protrudes from the top surface of the area surrounding the recessed portion 38a and 38b (this is an area of the semiconductor layer 35) is polished and reduced using the CMP (Chemical Mechanical Polishing) technology, until the top surface portion of the metal film layer 39 is flush with the surrounding top edge surface. Accordingly, as shown in FIG. 6K, the source electrode 36 and the drain electrode 37 can be formed as embedded in the recessed portion 38a and 38b.

Next, for the semiconductor layer 35 that is present for the source electrode 36 and the drain electrode 37 formed as described above, and for the channel between the electrodes 36 and 37, an insulating film (not shown) made of SiNₓ is formed by plasma CVD, and a TFT 30 is formed. Further, transparent conductive film made of ITO is formed by sputtering over the insulating film, and patterned so that it functions as the pixel electrode 23 (see FIG. 3). This forms the pixel region. Next, planarizing layer 26 (see FIG. 3) is formed by a prescribed method (photolithography, for example).

Next, by an inkjet method, for example, the constituting material for an alignment film (polyimide material, for example) is applied on the planarizing layer 26. Then, a rubbing treatment (a treatment in which the film is rubbed with cloth along a prescribed direction, for example) for controlling the alignment of liquid crystal molecules is conducted to form an alignment film 27.

The array substrate 12 is manufactured in the manner described above.

Next, a CF substrate 14 is manufactured. The CF substrate 14 can be manufactured in a manner similar to the conventional method. Photolithography is a preferable method, as in the case of the array substrate 12. In the method, first, black matrix 44, which will be a frame bordering color filters 42 of respective colors, is formed on the glass substrate main body 14a in a grid pattern typically by photolithography. Then, a R (red) pigment-dispersed resist (a resist material obtained by dispersing a red pigment in the transparent resin), for example, is applied uniformly over the glass substrate with the black matrix 44 formed thereon. Subsequently, a mask is aligned, exposure is conducted, and the pattern of the R color filter is printed. Next, development is conducted to form a R sub-pixel (color filter) patterned as prescribed. G (green) and B (blue) color filters are formed in the same manner. Then, a planarizing layer 46 and a transparent ITO conductive film destined to become opposite electrode 48 are formed over the color filter 42 and the black matrix 44 by sputtering, photolithography, or like method. An alignment film 47 can be formed over the opposite electrode 48 in the same manner as the alignment film 27 formed on the array substrate 12.

The CF substrate 14 is manufactured in the manner described above.

Using the array substrate 12 and the CF substrate 14 obtained as described above, a liquid crystal panel 10 is manufactured as described below. First, the array substrate 12 and the CF substrate 14 are bonded together (see FIG. 2 and FIG. 3). That is, for example, a sealing material (sealing adhesive made of thermosetting resin or ultraviolet-curable resin, for example) is applied along the border of the array substrate 12 to form a sealing member 15. Next, spacers 49 are dispersed over the array substrate 12 to provide an interval (gap) between the array substrate 12 and the CF substrate 14. Then, the CF substrate 14 is placed over the array substrate 12 for bonding so that the side having the alignment film 27 thereon and the side having the alignment film 47 formed thereon face each other.

Next, the pair of substrates 12 and 14 bonded together as described above is maintained in a vacuum environment, and liquid crystal material is introduced into the gap between the substrates by capillary action. Once the gap is filled with the liquid crystal material, the inlet is sealed. Lastly, polarizing plates 17 and 18 are attached to respective sides of the substrates 12 and 14 that are facing away from each other. In this way, the liquid crystal panel 10 is completed in this manner.

A bezel 60 and a frame 58 are attached to the front and back sides of the completed liquid crystal panel 10, respectively, to support the liquid crystal panel 10. On the back side of the frame 58, an optical member 57 and a backlight device 50 housed in a case 54 is attached. A liquid crystal display device 100 is configured in this manner.

Here, the difference between the array substrate 12 manufactured as described above and a conventional array substrate 212 is described with reference to FIG. 7, using the structure of TFT 230 as an example. In the multi-layered structure of TFT 230 of the conventional array substrate 212, as shown in FIG. 7, over the substrate main body 212a, a lower layer 232a, a middle layer 232b, and an upper layer 232c that constitute the gate electrode 232, and further, an insulating layer (gate insulating film) 234, and then a semiconductor layer 235 are layered. On the semiconductor layer 235, a source electrode 236 and a drain electrode 237 are formed. In the area between the electrodes 236 and 237 (the channel), the α-Si layer of the semiconductor layer 235 is present and covered by a channel protective film. Here, in the conventional array substrate 212, the top surface portions of the source electrode 236 and the drain electrode 237 protrude from the top edge surface of the channel or the top surface portion of the area surrounding the TFT 230 (pixel region). If the array substrate 212 having the source electrode 236 and the drain electrode 237, which protrude as described above, is used as a liquid crystal panel, the distance (space) between the array substrate 212 and the CF substrate, which faces the array substrate 212, is smaller (narrower) at the locations where the source electrode 236 and the drain electrode 237 are disposed. Therefore, if any impurities (foreign matters) are mixed in the liquid crystal layer sandwiched by the substrates, and the impurity is present at the location where the distance between the substrates is smaller, rather than at the location where the distance between the substrates is greater, unfavorable short-circuits can occur between the substrates at a higher rate.

On the other hand, as shown in FIG. 5 and FIG. 6K, for the array substrate 12 according to this embodiment, recessed portions 33a and 33b are formed in (the middle layer 32b of) the gate electrode 32. The source electrode 36 and the drain electrode 37 are formed as if they are surrounded by the semiconductor layer 35, and are embedded in the recessed portions 38a and 38b formed in the semiconductor layer 35 corresponding to the recessed portions 33a and 33b. As a result, the top surface portions of the source electrode 36 and drain electrode 37 do not protrude from, but are flush with the top edge surface of the semiconductor layer 35 surrounding the electrodes 36 and 37 without any level difference. Therefore, for the liquid crystal panel 10 (see FIG. 3) in which the array substrate 12 and the CF substrate 14 are disposed facing each other, the space between the substrates 12 and 14 where the source electrode 36 and the drain electrode 37 are located is maintained about the same as the space between the substrates for the area around the electrodes 36 and 37. Consequently, with the liquid crystal panel 10 according to this embodiment, a liquid crystal panel that is capable of preventing, at a high level, short-circuits from occurring between the substrates 12 and 14 can be provided.

While the present invention is described herein with reference to preferred embodiments, it should be understood that the invention is not limited thereto and various changes can be made.

In the embodiment described above, although the source electrode 36 and drain electrode 37 of the TFT 30 of the array substrate 12 are respectively disposed over the recessed portions 33a and 33b formed in the gate electrode 32, in another embodiment, for example, at the intersecting portion of a gate wire (bus line) and a source wire on the array substrate, the source wire may be formed in a recessed portion provided on the gate wire. Such embodiment is described with reference to FIG. 8. FIG. 8 is a plan view schematically showing the intersecting portion P of a gate wire 82 and a source wire 84 of an array substrate 80 according to another embodiment. For simplicity, the source wire 84 and the gate wire 82 are illustrated as having the same line width.

The array substrate 80 of this embodiment includes, in the pixel region, a plurality of intersecting portions P, where gate wires 82, which supply on/off signals of TFTs, and source wires 84, which supply display signals (signal voltages) to TFTs, cross each other. The array substrate 80 can also be applied to the array substrate 12 of the embodiment shown in FIG. 4, and in that case, the intersecting portion P includes a portion P₁, which is where a gate wire 22 and a source wire 24 intersect, and an intersecting portion P₂, which is where a bus line 28 and the source wire 24 intersect and does not have a TFT 30 in proximity.

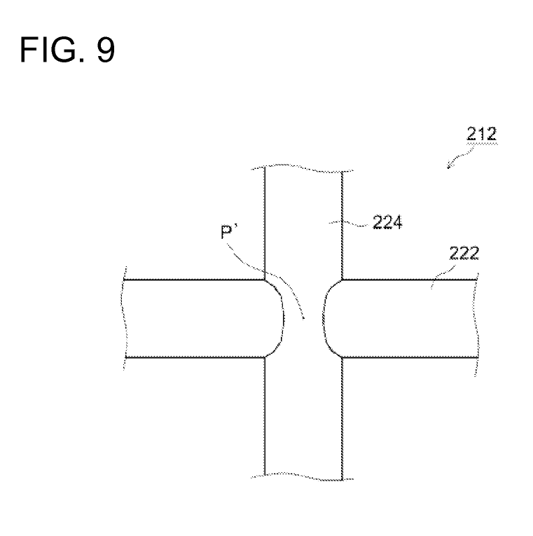

Here, as shown in FIG. 8, a recessed portion (not shown) is formed for the gate wire 82 at the intersecting portion P where the gate wire 82 intersects with the source wire 84. The recessed portion concaves in from the surrounding surface of the non-intersecting portion Q adjacent to the intersecting portion P. The source wire 84 passes through the recessed portion and at the recessed portion it crosses the gate wire 82. Because the intersecting portion P of the gate wire 82 concaves in, and the source wire 84 crosses the gate wire 82 over the recessed portion, the situation where the source wire 84 climbs over the gate wire 82 can be avoided. Consequently, any difference in the exposure depth, which can be generated between the intersecting portion P and non-intersecting portion Q when a metal film layered for patterning the source wire 84 is exposed, can be reduced. If the difference in the exposure depth is significant, the line width can be reduced and a line breakage can occur, as shown in FIG. 9, at the intersecting portion P′ where a conventional source wire 224 crosses the gate wire 222. However, as shown in FIG. 8, the source wire 84 does not experience any line width reduction due to the difference in the exposure depth in the intersecting portion P, and therefore is formed with about the same line width as in the non-intersecting portion Q.

Also, compared to the case where the source wire 224 is disposed over a conventional gate wire 222, which has no recessed portions, the source wire 84 has a smaller thickness (height) in the direction of the rise of the source wire 84 at the intersecting portion P, but is formed deeper as much as the depth of the recessed portion. Therefore, the source wire 84 obtains enough width and thickness in both the directions of the width and the depth at the intersecting portion P. Consequently, with the array substrate 80, a metal wiring (gate wire 82 and source wire 84) for which enough width and thickness are secured to avoid wire breakages can be formed.

Furthermore, in a liquid crystal panel equipped with the array substrate 80, with the presence of the recessed portion, the situation where the source wire 84 climbs over the gate wire 82 when it crosses the gate wire 82 can be avoided. With this configuration, the distance between the array substrate 80 and the CF substrate at the intersecting portion P is maintained about the same as the distance between the substrates at the non-intersecting portion Q. As a result, even if an impurity is mixed in at the intersecting portion P, for example, short-circuits between the substrates at the intersecting portion P can be prevented from occurring.

### INDUSTRIAL APPLICABILITY

According to an array substrate for liquid crystal panel of the present invention, a metal wiring for which enough width and thickness are maintained to avoid wire breakage while its overall thickness is suppressed to small can be formed, and a thin liquid crystal panel having a structure in which the heights (thicknesses) of the intersecting portions of the metal wiring and the TFT region are suppressed to small and therefore short-circuits between the substrates facing each other are hard to occur can be constituted.

### DESCRIPTION OF REFERENCE CHARACTERS

10 liquid crystal panel
12 array substrate
12a substrate main body
13 liquid crystal layer
14 color filter (CF) substrate
14a substrate main body
15 sealing member
16 external driver circuit
17, 18 polarizing plate
22 gate wire
23 pixel electrode
24 source wire
26 planarizing layer
27 alignment film
30 thin film transistor (TFT)
32 gate electrode
32a lower layer
32b middle layer
32c upper layer
33a, 33b recessed portion
34 insulating layer
35 semiconductor layer
36 source electrode
37 drain electrode
38a, 38b recessed portion
39 metal film layer
42 color filter
44 black matrix
46 planarizing layer
47 alignment film
48 opposite electrode
49 spacer
50 backlight device
52 light source
54 case
56 reflective member
57 optical member
58 frame
60 bezel
72, 74, 76 resist
80 array substrate
82 gate wire
84 source wire
100 liquid crystal display device

1. An array substrate for liquid crystal panel, comprising a substrate main body, a plurality of gate wires, a plurality of source wires crossing said gate wires, and a plurality of thin film transistors electrically connected to respective gate wires and source wires,
wherein said gate wires arranged on said substrate main body are formed to concave in at locations intersecting with said source wires to form portions that are recessed below a non-intersecting portion adjacent to an intersecting portion, and
wherein said source wires are arranged to cross said gate wires over the recessed portions of said gate wires.

2. The array substrate for liquid crystal panel according to claim 1, wherein a width of a top surface of said source wire is nearly constant at said intersecting portion and at portions adjacent to both sides of said intersecting portion.

3. An array substrate for liquid crystal panel, comprising a substrate main body, a plurality of gate wires, a plurality of source wires crossing said gate wires, and a plurality of thin film transistors electrically connected to respective gate wires and source wires,
wherein said thin film transistor has a multi-layered structure that includes a gate electrode formed on said substrate main body, an insulating layer formed over said gate electrode, a semiconductor layer formed over said insulating layer, and a source electrode and a drain electrode formed over said semiconductor layer, and
wherein respective portions of said gate electrode that are located under said source electrode and said drain electrode are formed as recessed below a surrounding portion, and said source electrode and said drain electrode are formed over said recessed portions.

4. The array substrate for liquid crystal panel according to claim 3,
wherein the source electrode and the drain electrode formed over said recessed portions are surrounded by another layer formed immediately below said electrodes, and
wherein top surface portions of said electrodes are flush with a top edge surface of said layer surrounding said electrodes, without any level difference.

5. The array substrate for liquid crystal panel according to claim 3, wherein said gate electrode has a multi-layered structure composed of two layers or three or more layers, and said recessed portions are formed in a lower layer portion excluding a top layer of said multi-layered structure.

6. A liquid crystal panel comprising the array substrate according to claim 1.

7. A liquid crystal display device comprising the liquid crystal panel according to claim 6.
